(19) United States
(12) Patent Application Publication
(10) Pub. No.: US 2019/0156883 A1
(43) Pub. Date: May 23, 2019

(54) NEUROMORPHIC COMPUTING DEVICE

(71) Applicant: MACRONIX INTERNATIONAL CO., LTD., Hsinchu (TW)

(72) Inventors: Yu-Yu Lin, New Taipei City (TW); Feng-Min Lee, Hsinchu City (TW)

(21) Appl. No.: 15/817,437

(22) Filed: Nov. 20, 2017

(51) Int. Cl. G11C 11/54; G11C 13/00; G06N 3/063; G06F 7/544

(52) U.S. Cl. CPC G11C 11/54; G06F 7/5443; G06N 3/0635; G11C 13/0002

(57) ABSTRACT

A neuromorphic computing device includes a plurality of row lines, a plurality of column lines and a plurality of synapses. The synapses are positioned at intersections of the row lines and column lines, respectively. The synapses include a first synapse and a second synapse. The first synapse includes a first resistance-adjustable element and a first transistor connected to the first resistance-adjustable element in series. The first transistor has a first aspect ratio and is configured to receive a first turn-on voltage. The second synapse includes a second resistance-adjustable element and a second transistor connected to the second resistance-adjustable element in series. The second transistor has a second aspect ratio and is configured to receive a second turn-on voltage. The first aspect ratio differs from the second aspect ratio, and/or the first turn-on voltage differs from the second turn-on voltage.

### TECHNICAL FIELD

The present invention generally relates to a neuromorphic computing device, in particular to a neuromorphic computing device implemented by using a memory array hardware structure.

### BACKGROUND

Recently, neuromorphic computing devices implemented by using memory arrays are proposed. Compared to those devices using processors to perform neuromorphic computations, the neuromorphic computing device has advantages of low power consumption.

The neuromorphic computing device usually includes a plurality of synapses, with each of which corresponds to a weighting value. When an input vector is applied to the neuromorphic computing device, the input vector is multiplied by a weighting vector consists of weighting values corresponding to one or more synapse relating to the input vector, so that a result of sum-of-product is obtained. The sum-of-product calculation is widely used in neuromorphic computing devices.

Typically, a synapse includes a ReRAM and a transistor connected in series and forming “1S1R” circuit structure. The ReRAM is used to represent different weighting values. The transistor functions as a switch element. However, the resistance of ReRAM suffers from adverse issues such as cell distribution, un-stability, retention and resistance drift, and thus the resistance of ReRAM is hard to be controlled at a desired value, causing that the synapse fails to provide a required weighting value, thereby affecting the accuracy and stability of the neuromorphic computing device.

### SUMMARY

The present invention generally relates to a neuromorphic computing device implemented by using memory array hardware structure. According to embodiments of the present invention, the neuromorphic computing device includes a resistance-adjustable element and a transistor, wherein the weighting value represented by the synapse is dominated by the conductivity of the transistor. The resistance-adjustable element is merely used as a switch element. Because the conductivity of the transistor can be controlled precisely by adjusting the magnitude of the turn-on voltage applied to the transistor and/or the aspect ratio (W/L) of the transistor, the accuracy and stability for the sum-of-product calculation is improved. Further, because the resistance-adjustable element functions as a switch element, of which the resistance is simply set at a low resistance state or a high resistance state, it is advantageous to use the resistance-adjustable element, together with the conductivity-adjustable transistor discussed above, to implement a multi-bit/multi-level weighting value for the sum-of-product calculation.

According to one aspect of the present invention, a neuromorphic computing device is provided. The neuromorphic computing device includes a plurality of row lines, a plurality of column lines and a plurality of synapses. The synapses are positioned at intersections of the row lines and column lines, respectively. The synapses include a first synapse and a second synapse. The first synapse includes a first resistance-adjustable element and a first transistor connected to the first resistance-adjustable element in series. The first transistor has a first aspect ratio and is configured to receive a first turn-on voltage. The second synapse includes a second resistance-adjustable element and a second transistor connected to the second resistance-adjustable element in series. The second transistor has a second aspect ratio and is configured to receive a second turn-on voltage. The first aspect ratio differs from the second aspect ratio, and/or the first turn-on voltage differs from the second turn-on voltage.

According to another aspect of the present invention, a neuromorphic computing device adapted to perform a sum-of-product calculation on an input vector is provided. The neuromorphic computing device includes a plurality of row lines, a plurality of column lines and a plurality of synapses. The row lines are configured to receive the input vector. The column lines are configured to output a result of sum-of-product of the input vector and a weighting vector. The synapses are positioned at intersections of the row lines and column lines and configured to form the weighting vector. The synapses include a first synapse and a second synapse. The first synapse includes a first resistance-adjustable element and a first transistor connected to the first resistance-adjustable element in series. The first resistance-adjustable element may be set at a low resistance state or a high resistance state. When the first resistance-adjustable element is set at the low resistance state, a first conductivity of the first transistor represents a first weighting value of the first synapse, wherein the first weighting value is included in the weighting vector. The second synapse includes a second resistance-adjustable element and a second transistor connected to the second resistance-adjustable element in series. The second resistance-adjustable element may be set at the low resistance state or the high resistance state. When the second resistance-adjustable element is set at the low resistance state, a second conductivity of the second transistor represents a second weighting value of the second synapse, wherein the second weighting value is included in the weighting vector.

### BRIEF DESCRIPTION OF THE DRAWINGS

FIG. 1 schematically illustrates the circuit structure of a neuromorphic computing device.

FIG. 2 is a top view of a partial circuit layout of a neuromorphic computing device in accordance with the first embodiment.

FIG. 3 is a top view of a partial circuit layout of a neuromorphic computing device in accordance with the second embodiment.

FIG. 4 is a top view of a partial circuit layout of a neuromorphic computing device in accordance with the second embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

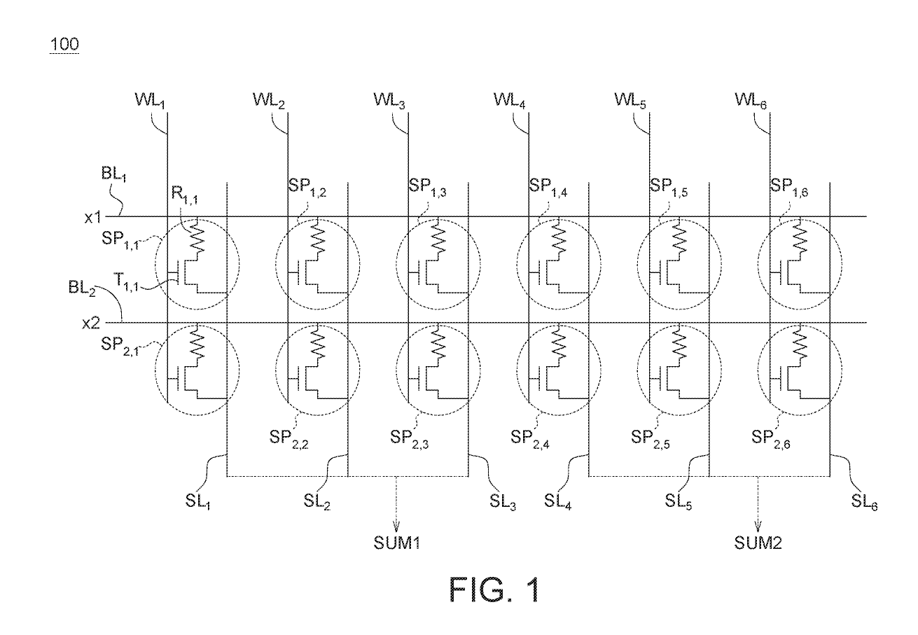

FIG. 1 schematically illustrates the circuit structure of a neuromorphic computing device 100. The neuromorphic device includes a plurality of row lines BL₁ and BL₂, a plurality of column lines SL₁ to SL₆, a plurality of word lines WL₁ to WL₆ and a plurality of synapses SP_{1,1} to SP_{1,6} and SP_{2,1} to SP_{2,6}The synapses SP_{1,1} to SP_{1,6} and SP_{2,1} to SP_{2,6} are positioned at intersections of the row lines BL₁, BL₂ and the column lines SL₁ to SL₆. Although the neuromorphic computing device 100 illustrated in FIG. 1 is exemplified by an array of 2×6 synapses, the present invention is not limited thereto. The neuromorphic computing device 100 may include M row lines, N column lines and M×N synapses positioned at the intersections of the row lines and column lines, wherein M and N are positive integers greater than 1.

The neuron neuromorphic computing device 100 may perform sum-of-product calculation on the input vector. The input vector described herein refers to a vector composed of one or more input values such as voltage values or current values. As shown, the row lines BL₁ and BL₂ respectively receive the input voltage x1 and x2. Therefore, the input vector may be represented as a one-dimension (1d) vector of [x1, x2].

The synapses SP_{1,1} to SP _{1,6} and SP_{2,1} to SP_{2,6} are configured to form a weighting vector comprised of one or more weighting values. For example, the weighting values of the synapses SP_{1,1} to SP_{1,6} at the first row are w11 to w16, respectively. The weighting values of the synapses SP_{2,1} to SP_{2,6} at the second row are w21 to w26, respectively. The weighting values w11 to w16 and w21 to w26 may be specified by conductivity of the transistors or any other appropriate physical quantity. For example, if the transistor is a MOS, the conductivity may refer to the ability of the transistor to conduct current between the drain terminal and the source terminal.

Each of the synapses includes a resistance-adjustable element and a transistor connected in series. As shown, the synapse includes a resistance-adjustable element R_{1,1} and a transistor T_{1,1}. The resistance-adjustable element may be a resistive random access memory (ReRAM), phase change random access memory (PCRAM), magnetoresistive random access memory (MRAM), fuse/anti-fuse device or other devices capable of providing a high resistance state and a low resistance state.

According to embodiments of the present invention, the resistance-adjustable element is used as a switch element that is binarily set at a low resistance state or a high resistance state to implement the ON/OFF function. The transistor is used as a weighting element that is configured to present a particular conductivity to determine the weighting value of the synapse.

The resistance-adjustable element may be set at the low resistance state to enable the synapse or at the high resistance state to disable the synapse. When a synapse is enabled, the corresponding weighting value of the enabled synapse is brought into the surd-of-product calculation. Otherwise, when the synapse is disabled, the corresponding weighting value of the disabled synapse is excluded from he sum-of-product calculation. This is because when the resistance-adjustable element is set at the high resistance state (i.e., the synapse is disabled), the synapse almost does not conduct current and does not contribute to the output current on the column line

The column lines SL₁ to SL₆ provides the result of sura-of-product by transmitting output currents. For example, provided that all the synapses SP₁₁ to SP₁₆ and SP₂₁ to SP₂₆ are enabled (i.e., the resistance-adjustable elements in these synapses are set at the low resistance state), the result of sum-of-product SUM1 can be obtained as follows by accumulating the output currents on the column lines SL₁ to SL₃.

$$SUM 1 = [ x 1 , x 2 ] \cdot [ \begin{matrix}w 11 & w 12 & w 13 \\ w 21 & w 22 & w 23\end{matrix} ] , \qquad ( equation 1 )$$

wherein the input vector is [x1, x2], and the weighting vector is

$$[ \begin{matrix}w 11 & w 12 & w 13 \\ w 21 & w 22 & w 23\end{matrix} ] .$$

Similarly, by collecting the output currents on the column lines SL₄ to SL₆, the result of sum-of-product SUM2 is obtained as follows:

$$SUM 2 = [ x 1 , x 2 ] \cdot [ \begin{matrix}w 14 & w 15 & w 16 \\ w 24 & w 25 & w 26\end{matrix} ] , \qquad ( equation 2 )$$

wherein the input vector is [x1, x2], and the weighting vector is

$$[ \begin{matrix}w 14 & w 15 & w 16 \\ w 24 & w 25 & w 26\end{matrix} ] .$$

Unlike a typical neuromorphic computing device, the magnitudes of the weighting values (e.g., w11 to w16, w21 to w26) in the weighting vector described above are dominated by the conductivity of the transistors of the synapses, rather by the resistance of the resistance-adjustable element. Instead, according to the proposed neuromorphic computing device, the resistance-adjustable element functions as a switch element. In this way, each weighting value can be precisely determined, and the adverse influences on the magnitudes of the weighting values such as cell distribution, un-stability, is retention, resistance drift can be avoided.

On the other hand, it can be observed that equation 1 can be re-written as follows:

SUM1=x1×W1+x2×W2,

wherein the equivalent weighting value W1=w11+w12+w13, and the equivalent weighting value W2=w21+w22w23.

Similarly, it is observed that equation 2 can be re-written as follows:

SUM2=x1×W3+x2×W4,

wherein the equivalent weighting value W3=w14+w15+w16, and the equivalent weighting value W4=w24+w25+w26.

As can be seen, in a result of sum-of-product (e.g., SUM1), a m lti-bitlmulti-level equivalent weighting value (e.g., W1) for an input voltage (e.g., x1) may be obtained from a combination of synapses (e.g., SP_{1,1}, SP_{1,2} and SP_{1,3}) receiving the input voltage. For example, if w11:w12:w13 equals to 1:2:4, W1 can be expressed as a binary 3-bit value (8 levels).

According to embodiments of the present invention, the conductivity of a transistor determining the weighting value of a synapse is adjusted by at least one of (1) the turn-on voltage applied to the transistor and (2) the aspect ratio (W/L) of the transistor. The “turn-on voltage” may refer to a voltage applied to the control terminal (e.g., the gate terminal for MOS or the base terminal for BJT) of a transistor through a word line (e.g., WL₁) that is sufficient to turn on the transistor and operate the transistor in a triode region. For better comprehension, the first to third embodiments are described below. However, it should be noted that the present invention is not limited by the contents of the exemplary embodiments.

### First Embodiment

According to the first embodiment, transistors in different synapses may have different aspect ratio. Therefore, the transistors in the synapses may respond the same turn-on voltage to present different conductivity, so that the weighting values of the respect synapses are determined.

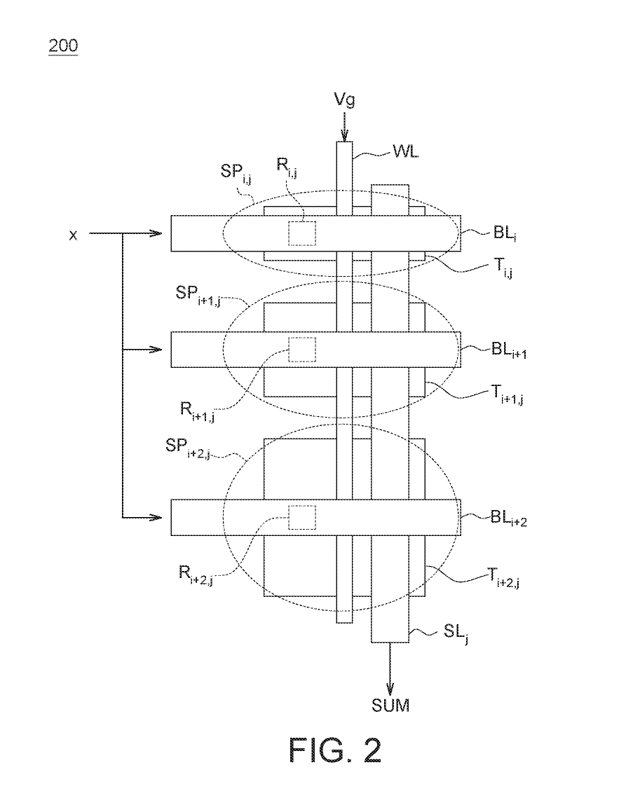

FIG. 2 is a top view of a partial circuit layout of a neuromorphic computing device 200 in accordance with the first embodiment. The neuromorphic computing device 200 includes row lines BLᵢ, BL₁₊₁, BLᵢ₊₂, a column line SLⱼ, a word line WL and synapses SP_{i,j}, SP_{i+1,j}, SP_{i+2,j}. Although 3×1 synapses are shown in FIG. 2, it should be noted that any quantity and combination of the synapses may be included in the neuromorphic computing device 200.

In this embodiment, the row lines BLᵢ to BLᵢ₊₂ are formed on the second metal layer (M2). The column line SLⱼ is formed on the first metal layer (M1) under the second metal layer. The synapses SP_{i,j}, P_{i+1,j}, SP_{i+2,j} receive the turn-on voltage Vg through the word line WL.

The synapse SP_{i,j} includes a resistance-adjustable element R_{i,j} and a transistor T_{i,j}. The synapse SP_{i+1,j} includes a resistance-adjustable element R_{i+1,j} and a transistor T_{i+1,j}. The synapse SP_{i+2,j} includes a resistance-adjustable element R_{i+2,j} and a transistor T_{i+2,j}. As shown in the figure, the transistors T_{i,j}, T_{i+1,j} and T_{i+2,j} have different sizes. That is, the transistors T_{i,j}, T_{i+1,j} and T_{i+2,j} have a first aspect ratio, a second aspect ratio and a third aspect ratio, respectively.

Each of the transistors T_{i,j}, T_{i+1,j} and T_{i+2,j} formed on the substrate is electrically connected to the column line SLⱼ of the first metal layer. In response to the input voltage x applied to the row lines BLᵢ to BLᵢ₊₂, the transistors T_{i,j}, T_{i+1,j} and T_{i+2,j} generates output currents on the column line SLⱼ. The total output current on the column line SLⱼ is corresponding to a result of sum-of-product SUM for the input voltage x.

The resistance-adjustable element R_{i,j} is electrically connected between the transistor T_{i,j} and the row line BLᵢ. The resistance-adjustable element R_{i+1,j} is electrically connected between the transistor T_{i+1,j} and the row line BLᵢ₊₁. The resistance-adjustable element Rᵢ₊₂ is electrically connected between the transistor T_{i+2,j} and the row line BLᵢ₊₂.

The word line WL is electrically connected to the control terminals of the transistors T_{i,j}, T_{i+1,j}, T_{i+2,j}, and is configured to transmit turn-on voltage Vg to each transistor T_{i,j}, T_{i+1,j}, T_{i+2,j}.

With the combination of the synapses SP_{i,j}, SP_{i+1,j}, SP_{i+2,j}, an equivalent weighting value w for the input voltage x is implemented. For example, by appropriately configuring the aspect ratio of each transistor T_{i,j}, T_{i+1,j}, T_{i+2,j}, the transistors T_{i,j}, T_{i+1,j}, T_{i+2,j} may present individual conductivity σ₁, σ₂ and σ₃, respectively in response to the turn-on voltage Vg, wherein the conductivity σ₁, σ₂ and σ₃ are respectively corresponding to (or epresented as) the weighting values of the synapses SP_{i,j}, SP_{i+1,j}, SP_{i+2,j}.

In an example, the ratio between two different conductivity may be the n^{th} power of 2, where n is integral. For example, σ₁:σ₂:σ₃ may be 1:2:4, so that a binary 3-bit equivalent weighting value w is implemented. Specifically, if the low resistance state of a resistance-adjustable element is represented as bit “1” and the high resistance state of the resistance-adjustable element is represented as bit “0,” when all of the resistance-adjustable elements R_{i,j}, R_{i+1,j}, R_{i+2,j} are set at the low resistance state (1, 1, 1), all the transistors T_{i,j}, T_{i+1,j}, T_{i+2,j} make contribution to the output current, so that the total output current on the column line SLⱼ is maximum. At this time, the equivalent weighting value w equals to 7 (=1+2=4). Likewise, when the resistance states of the resistance-adjustable elements R_{i,j}, R_{i+1,j}, R_{i+2,j} are (1, 0, 1), only the transistors T_{i,j} and T_{i+2,j} contribute to the output current. At this e, the equivalent weighting value w equals to 5 (=1+2=4).

In other examples, the ratio between the conductivity of different transistors is arbitrary.

For getting better accuracy, the conductivity (σₒₙ) of the resistance-adjustable element being set at the low resistance state may be taken into consideration when determining the weighting values of the synapses. For example, in order to use the synapses SP_{i,j}, SP_{i+1,j}, SP_{i+2,j} to implement a 3-bit equivalent weighting value w, the ratio of σ₁//σₒₙ:σ₂//σₒₙ:σ₃//σₒₙ may be configured as 1:2:4.

### Second Embodiment

According to the second embodiment, transistors in different synapses may have the same aspect ratio and receive different turn-on voltages to present different conductivity, so that the weighting values of respect synapses are determined.

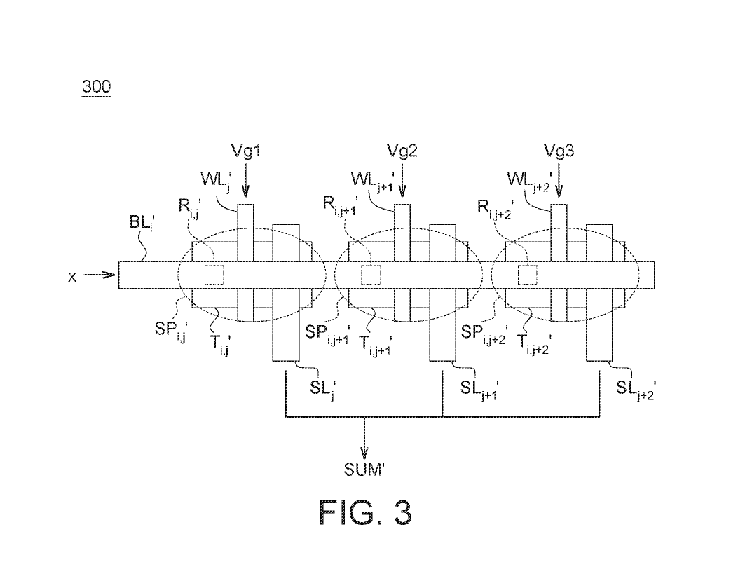

FIG. 3 is a top view of a partial circuit layout of a neuromorphic computing device 300 in accordance with the second embodiment. The neuromorphic computing device 300 includes a row line BLᵢ′, column lines SLⱼ′, SPⱼ₊₁′, SPⱼ₊₂′, word lines WLᵢ′, Wⱼ₊₁′, WLⱼ₊₂′ and synapses SP_{i,j}′, SP_{i,j+1}′, SP_{i,j+2}′. Although 1×3 synapses are shown in FIG. 3, it should be noted that any quantity and combination of the synapses may be included in the neuromorphic computing device 300.

The row line BLᵢ′ is formed on the second metal layer. The column lines SLⱼ′, SLⱼ₊₁′, SLⱼ₊₂′ are formed on the first metal layer under the second metal layer. The synapses SP_{i,j}′, SP_{i,j+1}′ and SP_{i,j+2}′ receive turn-on voltages Vg1, Vg2 and Vg3 with different magnitudes through the word lines WLⱼ′, WLⱼ₊₁′ and WLⱼ₊₂′, respectively.

The synapse includes a resistance-adjustable element R_{i,j}′ and a transistor T_{i,j}′. The synapse SP_{i,j+1}′ includes a resistance-adjustable element R_{i,j+1}′ and a transistor T_{i,j+1}′. The synapse SP_{i,j,2}′ includes a resistance-adjustable element R_{i,j+2}: and a transistor T_{i,j+2}′. The transistors T_{i,j}′, T_{i,j+1}′, T_{i,j+2}′ may have the same size. The transistors T_{i,j}′, T_{i,j+1}′, T_{i,j+2}′ are electrically connected to the column lines SLⱼ′, SLⱼ₊₁′, and SLⱼ₊₂′ formed on the first metal layer, respectively.

The resistance-adjustable element R_{i,j}′ is electrically connected between the transistor T_{i,j}′ and the row line BLᵢ′. The resistance-adjustable element R_{i,j+1}′ is electrically connected between the transistor T_{i,j+1}′ and the row line BLᵢ′. The resistance-adjustable element R_{i,j+2}′ is electrically connected between the transistor T_{i,j+2}′ and the row line BLᵢ′.

The turn-on voltages Vg1, Vg2 and Vg3 are applied to the control terminals of the transistors T_{i,j}′, T_{i,j+1}′, T_{i,j+2}′ through the word lines WLⱼ′, WLⱼ₊₁′, WLⱼ₊₂′, respectively. The input voltage x′ is applied to the row line BLᵢ′. In response to the input voltage x′, the synapses SP_{i,j}′, T_{i,j+1}′, T_{i,j+2}′ generate corresponding output currents on the column lines SLⱼ′, SLⱼ₊₁′, SLⱼ₊₂′, respectively. The summation of the output currents may be used to represent a result of sum-of-product SUM′, which is almost equal to the product of the input vector x and an equivalent weighting value w′ determined by the synapses SP_{i,j}′, SP_{i,j+1}′, SP_{i,j+2}′.

By appropriately configuring the magnitudes of the turn-on voltages Vg1, Vg2, Vg3, the transistors T_{i,j}′, T_{i,j+1}′, T_{i,j+2}′ may present conductivity σ₁′, σ₂′ and σ₃′, respectively, wherein the conductivity σ₁′, σ₂′ and σ₃′ respectively represent the weighting values of the synapses SP_{i,j}′, SP_{i,j+1}′, SP_{i,j+2}′. The ratio between the conductivity σ₁′: σ₂′: σ₃′ may be arbitrary, e.g., 1:2:4 or 1:1:1.

To get better accuracy, the conductivity (σₒₙ) of the resistance-adjustable element being set at the low resistance state is taken into consideration when determining the weighting values of the synapses. For example, in order to implement a 3-bit equivalent weighting value w′ by using the synapses SP_{i,j}′, SP_{i,j+1}′, SP_{i,j+2}′, the ratio of σ₁′//σₒₙ: σ₂′//σₒₙ: σ₃′//σₒₙ may be configured as 1:2:4 by adjusting the magnitudes of the turn-on voltages Vg1, Vg2 and Vg3.

### Third Embodiment

According to the third embodiment, transistors in different synapses may have different aspect ratios and receive different turn-on voltages to present different conductivity, so that the weighting values of respect synapses are determined.

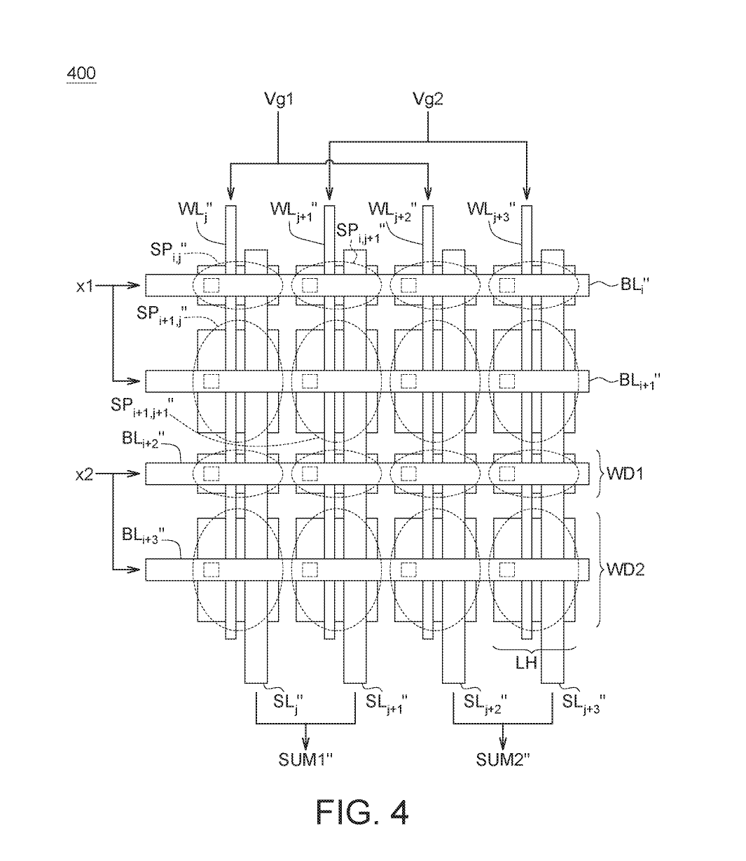

FIG. 4 is a top view of a partial circuit layout of a neuromorphic computing device 400 in accordance with the second embodiment. The neuromorphic computing device 400 includes row lines BLᵢ″ to BLᵢ₊₃″, column lines SLⱼ″ to SLⱼ₊₃″, word lines WLⱼ″ to WLⱼ₊₃″ and 4×4 synapses. Although 4×4 synapses are shown in FIG. 4, it should be noted that any quantity and combination of the synapses may be included in the neuromorphic computing device 400.

The turn-on voltage Vg1 is applied to the word lines WLⱼ″ and WLⱼ₊₂″, and the turn-on voltage Vg2 is applied to the word lines WLⱼ₊₁″ and WLⱼ₊₃′.

The synapses coupled to the row lines BLᵢ″ and BLᵢ₊₁″ receive the input voltage x1. The synapses coupled to the row lines BLᵢ₊₂″ and BLᵢ₊₃″ receive the input voltage x2. By collecting the output currents on the column lines SLⱼ″ and SLⱼ₊₁″, a result of sum-of-product SUM1″ is obtained. By collecting the output currents on the column lines SLⱼ₊₂″ and SLⱼ₊₃″, a result of sum-of-product SUM2″ is obtained.

According to FIG. 3, the transistors in the synapses SP_{i,j}″ and SP_{i,j+1}″ have the same aspect ratio (=WD1/LH). The transistors in the synapses SP_{i+1,j}″and SP_{i+1,j+1}″ have the same aspect ratio (=WD2/LH).

By appropriately configuring the aspect ratios of the transistors and the magnitudes of the turn-on voltages, the weighting values of the synapses SP_{i,j}″, SP_{i,j+1}″, SP_{i+1,j}″ and SP_{i+1,j+1}″ are configured as w11″, w12″, w21″ and w22″, respectively. The magnitude of the weighting values w11″, w12″, w21″, w22″ can be arbitrary, depending on the conductivity of the transistors in the synapses SP_{i,j}″, SP_{i,j+1}″, SP_{i+1,j}″ and SP_{i+1,j+1}″ In an example, the turn-on voltage Vg1 is less than Vg2, and the aspect ratio (WD1 /LH) is less than (WD2/LH), so that the ratio between the weighting values w11″:w12″:w21″:w22″ is about 1:2:4:8, thereby realizing a binary 4-bit (16 levels) equivalent weighting value w″ through the synapses SP_{i,j}″, SP_{i,j+1}″, SP_{i+1,j}″ and SP_{i+1,j+1}″.

Based on the above, the present invention generally relates to a neuromorphic computing device implemented by using memory array hardware structure. According to embodiments of the present invention, the neuromorphic computing device includes a resistance-adjustable element and a transistor, wherein the weighting value represented by the synapse is dominated by the conductivity of the transistor. The resistance-adjustable element is merely used as a switch element. Because the conductivity of the transistor can be controlled precisely by adjusting the magnitude of the turn-on voltage applied to the transistor and/or the aspect ratio (W/L) of the transistor, the accuracy and stability for the sum-of-product calculation is improved. Further, because the resistance-adjustable element functions as a switch element, of which the resistance is simply set at a low resistance state or a high resistance state, it is advantageous to use the resistance-adjustable element, together with the conductivity-adjustable transistor discussed above, to implement a multi-bitlmulti-level weighting value for the sum-of-product calculation.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A neuromorphic computing device comprising:
a plurality of row lines;
a plurality of column lines; and
a plurality of synapses, positioned at intersections of the row lines and column lines, respectively, the synapses comprising:
a first synapse comprising:
a first resistance-adjustable element configured to be binarily set at a low resistance state or a high resistance state to function as a first switch element; and
a first transistor, connected to the first resistance-adjustable element in series, the first transistor having a first aspect ratio and being configured to receive a first turn-on voltage; and
a second synapse comprising:
a second resistance-adjustable element configured to be binarily set at a low resistance state or a high resistance state to function as a second switch element; and
a second transistor, connected to the second resistance-adjustable element in series, the second transistor having a second aspect ratio and being configured to receive a second turn-on voltage;
wherein the first aspect ratio differs from the second aspect ratio, and/or the first turn-on voltage differs from the second turn-on voltage.

2. The neuromorphic computing device according to claim 1, wherein the neuromorphic computing device is configured to perform a sum of product calculation on an input vector, the row lines are configured to receive the input vector, the column lines are configured to output a result of sum-of-product of the input vector and a weighting vector, and the synapses are configured to form the weighting vector.

3. (canceled)

4. The neuromorphic computing device according to claim 3, wherein a first conductivity of the first transistor receiving the first turn-on voltage determines a first weighting value included in the weighting vector, and a second conductivity of the second transistor receiving the second turn-on voltage determines a second weighting value included in the weighting vector.

5. The neuromorphic computing device according to claim 4, wherein the magnitudes of the first turn-on voltage and the second turn-on voltage are the same, and the first aspect ratio of the first transistor and the second aspect ratio of the second transistor are different.

6. The neuromorphic computing device according to claim 5, wherein the first synapse and the second synapse are coupled to two of the row lines, and receive the first turn-on voltage and the second turn-on voltage through a word line.

7. The neuromorphic computing device according to claim 5, wherein a ratio between the first conductivity and the second conductivity is about nth power of 2, wherein n is an integral.

8. The neuromorphic computing device according to claim 4, wherein the first aspect ratio of the first transistor and the second aspect ratio of the second transistor are the same, and the magnitudes of the first turn-on voltage and the second turn-on voltage are different.

9. The neuromorphic computing device according to claim 8, wherein the first synapse and the second synapse are coupled one of the row lines, and receive the first turn-on voltage and the second turn-on voltage through different word lines.

10. The neuromorphic computing device according to claim 7, wherein a ratio between the first conductivity and the second conductivity is about nth power of 2, wherein n is an integral.

11. The neuromorphic computing device according to claim 4, wherein the first aspect ratio of the first transistor and the second aspect ratio of the second transistor are different, and the magnitudes of the first turn-on voltage and the second turn-on voltage are different.

12. The neuromorphic computing device according to claim 11, wherein the first synapse and the second synapse are coupled to different two of the row lines and two of the column lines, and receive the first turn-on voltage and the second turn-on voltage through different word lines.

13. The neuromorphic computing device according to claim 9, wherein a ratio between the first conductivity and the second conductivity is about nth power of 2, wherein n is an integral.

14. A neuromorphic computing device, adapted to perform a sum-of-product calculation on an input vector, the neuromorphic computing device comprising:
a plurality of row lines configured to receive the input vector;
a plurality of column lines configured to output a result of sum-of-product of the input vector and a weighting vector; and
a plurality of synapses positioned at intersections of the row lines and column lines, respectively, and configured to form the weighting vector, the synapses comprising:
a first synapse comprising:
a first resistance-adjustable element, configured to be binarily set at a low resistance state or a high resistance state to function as a first switch element; and
a first transistor, connected to the first resistance-adjustable element in series, wherein when the first resistance-adjustable element is set at the low resistance state, a first conductivity of the first transistor represents a first weighting value of the first synapse, the first weighting value is included in the weighting vector; and
a second synapse comprising:
a second resistance-adjustable element, configured to be binarily set at the low resistance state or the high resistance state to function as a second switch element; and
a second transistor, connected to the second resistance-adjustable element in series, wherein when the second resistance-adjustable element is set at the low resistance state, a second conductivity of the second transistor represents a second weighting value of the second synapse, and the second weighting value is included in the weighting vector.

15. The neuromorphic computing device according to claim 14, wherein the magnitudes of the first turn-on voltage and the second turn-on voltage are the same, and the first aspect ratio of the first transistor and the second aspect ratio of the second transistor are different.

16. The neuromorphic computing device according to claim 15, wherein the first synapse and the second synapse are coupled to two of the row lines, and receive the first turn-on voltage and the second turn-on voltage through a word line.

17. The neuromorphic computing device according to claim 14, wherein the first aspect ratio of the first transistor and the second aspect ratio of the second transistor are the same, and the magnitudes of the first turn-on voltage and the second turn-on voltage are different.

18. The neuromorphic computing device according to claim 17, wherein the first synapse and the second synapse are coupled one of the row lines, and receive the first turn-on voltage and the second turn-on voltage through different word lines.

19. The neuromorphic computing device according to claim 14, wherein the first aspect ratio of the first transistor and the second aspect ratio of the second transistor are different, and the magnitudes of the first turn-on voltage and the second turn-on voltage are different.

20. The neuromorphic computing device according to claim 19, wherein the first synapse and the second synapse are coupled to different two of the row lines and two of the column lines, and receive the first turn-on voltage and the second turn-on voltage through different word lines.
